(19) United States
(12) Patent Application Publication
(10) Pub. No.: US 2009/0090998 A1
(43) Pub. Date: Apr. 9, 2009

(54) SEMICONDUCTOR DEVICE AND MANUFACTURING METHOD THEREOF

(76) Inventor: Je-Sik Woo, Gwanak-gu (KR)

Correspondence Address: SHERR & VAUGHN, PLLC, 620 HERNDON PARKWAY, SUITE 200, HERNDON, VA, 20170, US

(21) Appl. No.: 12/244,886

(22) Filed: Oct. 3, 2008

(30) Foreign Application Priority Data
Oct. 8, 2007 (KR) 10-2007-0100716

(51) Int. Cl. H01L 29/92; H01L 21/4763

(52) U.S. Cl. 257/532; 438/399; 257/E21.495; 257/E29.343

(57) ABSTRACT

A semiconductor device includes a first and second structures formed in a first insulating layer, a lower metal interconnection formed in the second structure, a metal-insulator-metal (MIM) capacitor formed in the first structure, and first, second and third electrodes formed in the first structure and electrically connected to the MIM capacitor. The first electrode is a chip bottom metal (CBM) layer, the second electrode is a first chip top metal (CTM) layer and the third electrode is a second chip top metal (CTM) layer.

The present application claims priority under 35 U.S.C. §119 to Korean Patent Application No. 10-2007-0100716 (filed on Oct. 8, 2007), the contents of which are incorporated in its entirety.

### BACKGROUND

In order to fabricate a semiconductor device, a predetermined layer is formed on and/or over a wafer and a lithographic process is performed to a desired pattern. According to the lithography process, photoresist is coated on and/or over the wafer having the predetermined layer, the photoresist is exposed and developed using a mask, and then the layer on the wafer is etched using the photoresist pattern. The exposure process determines the accuracy of a semiconductor device manufacturing process. While the lithographic process is being repeated, a position of a pattern, which is formed through the previous process, must be aligned with a position of a pattern to be formed in the present process. Only when the mask pattern of a reticle and the wafer are located at the same position as that of the previous pattern forming step, interlayer patterns can be exactly aligned, so that the interlayer patterns can be electrically interconnected. Such an operation for aligning the interlayer patterns will be referred as alignment work, and a pattern used as a reference of the align work will be referred as an alignment key.

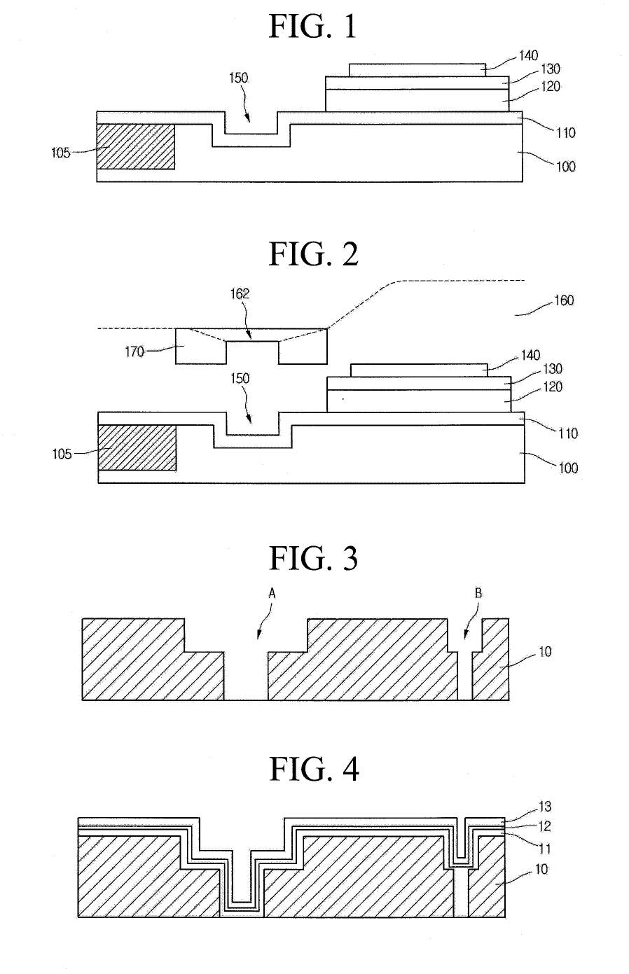

Example FIG. 1 illustrates a side sectional view of a semiconductor device after a capacitor device is formed. Example FIG. 2 illustrates a side sectional view of the semiconductor device of example FIG. 1 after a second metal interconnection layer is formed on and/or over the capacitor device.

As illustrated in example FIG. 1, second insulating layer 110 is formed on and/or over first insulating layer 100 having first metal interconnection layer 105 formed therein. Lower metal layer 120, insulating layer 130 and upper metal layer 140 are then sequentially laminated on and/or over a portion of second insulating layer 110, thereby completing fabrication of a metal-insulator-metal (MIM) capacitor. The MIM capacitor including lower metal layer 120, the insulating layer 130 and upper metal layer 140 is formed through a lithographic process similarly to first metal interconnection layer 105. As described above, a photoresist pattern for first metal interconnection layer 105 must be aligned with a photoresist pattern for the MIM capacitor. However, since a polishing process such as chemical mechanical polishing (CMP) is performed after first metal interconnection layer 105 is formed, the surface of first insulating layer 100 is planarized. Thus, since a stepped structure which can be used as an alignment key is removed, it is difficult to align the MIM capacitor with a lower layer.

In order to solve such a problem, trench-type stepped portion 150 is formed in the process of forming lower metal layer 120 and upper metal layer 140 of the MIM capacitor. Trench-type stepped portion 150 is used as an alignment key. However, such a method additionally requires a complicated process including a photolithographic process and the size of a scribe lane on and/or over which stepped portion 150 is positioned is increased. Thus, a substrate area may not be efficiently used. In particular, when the subsequent process is performed, trench-type stepped portion 150 may exert bad influence on and/or over the planarity of an upper layer.

As illustrated in example FIG. 2, for example, in a case in which second metal interconnection layer 170 is formed on and/or over the MIM capacitor, a CMP process is performed after laminating third insulating layer 160 and forming the trench. Third insulating layer 160 has different deposition heights by trench-type stepped portion 150 and the MIM capacitor and is not uniformly planarized as a result of a dishing phenomenon. In addition, area 162 corresponding to trench-type stepped portion 150 is deeply polished. Thus, when a plurality of trenches are formed while interposing the deeply polished area 162 therebetween, metal material may be filled in the deeply polished area 162 as well as the trenches. Thus, disconnection may occur between second metal interconnection layers 170 as illustrated in example FIG. 2.

### SUMMARY

Embodiments relate to a semiconductor device and a manufacturing method thereof which does not exert bad influence on the subsequent process, such as disconnection between metal interconnection layers formed later, by preventing topology difference between an area including an MIM capacitor and another semiconductor area.

Embodiments relate to a semiconductor device and a manufacturing method thereof in which an MIM capacitor can be formed together with metal interconnections through a simple process without forming a separate alignment key.

Embodiments relate to an apparatus that may include at least one of the following: a first insulating layer, a first structure formed in the first insulating layer, a second structure formed in the first insulating layer spaced from the first structure, a lower metal interconnection formed in the second structure, a metal-insulator-metal (MIM) capacitor formed in the first structure, a first electrode formed in the first structure and electrically connected to the MIM capacitor, a second electrode formed in the first structure and electrically connected to the MIM capacitor, and a third electrode formed in the first structure and electrically connected to the MIM capacitor.

Embodiments relate to a semiconductor device that may include at least one of the following: a first trench in a first insulating layer, a second trench in the first trench, a first metal layer in the first and second trenches, a second insulating layer on and/or over a portion of the first metal layer in the first and second trenches, a second metal layer on and/or over the second insulating layer, a CBM layer on and/or over a predetermined portion of the first metal layer in the second trench where the second insulating layer is not formed, a CTM layer on and/or over the second metal layer, and a third insulating layer between the CBM layer and the CTM layer.

Embodiments relate to a method for manufacturing a semiconductor device that may include at least one of the following steps: forming a dual trench including a first trench and a second trench formed in the first trench, in a first insulating layer, and then sequentially forming a first metal layer, a second insulating layer and a second metal layer on and/or over the first insulating layer including the dual trench, and then removing portions of the first metal layer, the second insulating layer and the second metal layer from the first insulating layer, while leaving portions of the first metal layer, the second insulating layer and the second metal layer formed on and/or over a dual trench area, and then forming a third insulating layer on and/or over the second metal layer located on and/or over the dual trench area, and then removing portions of the second insulating layer, the second metal layer and the third insulating layer from the second trench, and then removing a remaining portion of the third insulating layer from the second trench, and then removing a portion of the third insulating layer from the first trench, and then forming a CBM layer by filling metal in an area of the second trench where the portions of the second insulating layer, the second metal layer and the third insulating layer have been removed, and then forming a CTM layer by filling metal in an area of the second trench where the remaining portion of the third insulating layer has been removed and an area of the first trench where the portion of the third insulating layer is removed.

Embodiments relate to a method that may include at least one of the following steps: forming a first structure and a second structure spaced apart in a first insulating layer; and then forming a lower metal interconnection formed in the second structure; and then forming a metal-insulator-metal (MIM) capacitor in the first structure; and then simultaneously forming a second insulating layer pattern and a third insulating layer pattern spaced pattern apart in the first structure; and then simultaneously forming a first electrode, a second electrode and a third electrode spaced apart in the first structure and electrically connected to the MIM capacitor after simultaneously forming the second insulating layer pattern and the third insulating layer pattern such that the second insulating layer pattern is formed between the first electrode and the second electrode and the third insulating layer pattern is formed between the second electrode and the third electrode.

Embodiments relate to a semiconductor device that may include at least one of the following: a first insulating layer, a first structure formed in the first insulating layer, a second structure formed in the first insulating layer spaced from the first structure, a first metal interconnection formed in the second structure, a metal-insulator-metal (MIM) capacitor formed in the first structure, the MIM capacitor including a first metal layer, a second insulating layer and a second metal layer, a first electrode formed in the first structure and electrically connected to the MIM capacitor at the second metal layer, a second electrode formed in the first structure and electrically connected to the MIM capacitor at the first metal layer, a third electrode formed in the first structure and electrically connected to the MIM capacitor at the first metal layer, a third insulating layer formed over the first insulating layer, a second metal interconnection formed in the third insulating layer and electrically connected to the first electrode, a third metal interconnection formed in the third insulating layer and electrically connected to the second electrode and the third electrode, a fourth metal interconnection formed in the third insulating layer and electrically connected to the first metal interconnection.

### DRAWINGS

Example FIGS. 1 and 2 illustrate a semiconductor device having a capacitor device and a second metal interconnection layer formed on and/or over the capacitor device.

Example FIGS. 3 to 12 illustrate a semiconductor device in accordance with embodiments.

### DESCRIPTION

Hereinafter, a semiconductor device and a manufacturing method thereof in accordance with embodiments will be described with reference to the accompanying example drawing figures. For the purpose of convenience, the configuration and manufacturing method of the semiconductor device will be described based on the manufacturing procedure thereof.

As illustrated in example FIG. 3, a method of manufacturing a semiconductor device can include forming first insulating layer 10 on and/or over a semiconductor device having a lower metal interconnection formed therein. A photoresist is coated on and/or over first insulating layer 10. Next, the photoresist is selectively patterned through an exposure and development process to define a trench area. Then, first insulating layer 10 is selectively removed using the patterned photoresist as a mask to form a single damascene structure such as at least one of trench and via. In accordance with embodiments, the process may be performed twice to form a dual damascene structure including first structure A having a first via and a first trench and second structure B having a second via and a second trench. A MIM capacitor may be formed in first structure A while a metal interconnection may be formed in second structure B.

Alternatively, first structure A where the MIM capacitor is formed may be referred to as dual trench A and the trench where the metal interconnection is formed may be referred to as third trench B. In such a situation, dual trench A includes a first trench and a second trench formed in the first trench to have a width greater than that of the first trench. Third trench B may also be prepared in the form of a dual trench. However, since this has no significant relation to the technical scope of embodiments, a detailed description thereof will be omitted.

As illustrated in example FIG. 4, first metal layer 11, second insulating layer 12 and second metal layer 13 are sequentially laminated on and/or over first insulating layer 10 including the via and trench of first structure A and the via and trench of second structure trench B. First metal layer 11 and second metal layer 13 may be composed of a titanium material such as one selected from the group consisting of Ti, TiN, Ti/TiN and Ti/Al/TiN, respectively. First metal layer 11 may have multi-structure including Ti/TiN and second metal layer 13 includes TiN. Second insulating layer 12 may be composed of a nitride such as SiN.

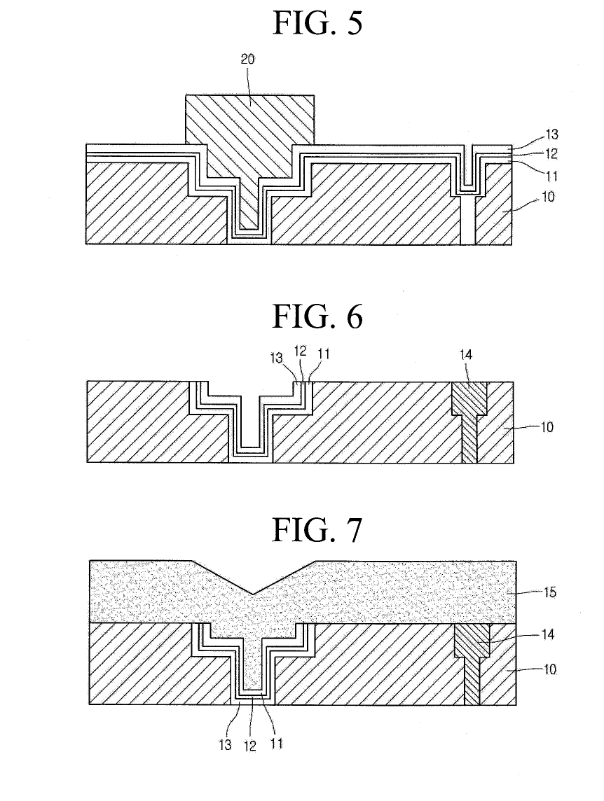

As illustrated in example FIG. 5, first photoresist pattern 20 is formed by coating a first photoresist on and/or over second metal layer 13 and then selectively patterning the first photoresist through an exposure and development process. First patterned photoresist 20 is used as an etch mask. Accordingly, a reticle used for the exposure and development process is aligned on the basis of a stepped portion of first structure A, so that first photoresist pattern 20 can be aligned with first structure A. For example, the stepped portion of first structure A can be used as an alignment key by using optical measurement equipment such as an SEM (scanning electronic microscope). The SEM irradiates an electronic beam on and/or over a wafer having a step difference, and detects secondary electrons reflected from the wafer to generate electric signals based on the secondary electrons. Then, the SEM performs the scan synchronization to obtain an SEM image, and identifies the step difference on the SEM image to use the step difference as the alignment key.

As illustrated in example FIG. 6, an etch process is then performed using first photoresist pattern 20 as a mask to remove portions of first metal layer 11, second insulating layer 12 and second metal layer 13 from the uppermost surface of first insulating layer 10 while leaving the remaining portion of first metal layer 11, second insulating layer 12 and second metal layer 13 on and/or over sidewalls and a bottom wall of first structure A. Simultaneously, first metal layer 11, second insulating layer 12 and second metal layer 13 are removed from second structure B. A metal material is filled in second structure B to form metal interconnection 14. First metal layer 11, second insulating layer 12 and second metal layer 13 remaining in first structure A can serve as a MIM capacitor.

As illustrated in example FIG. 7, after forming metal interconnection 14, an insulating layer composed an oxide material is coated in first structure A and on and/or over first insulating layer 10 including metal interconnection 14 to form third insulating layer 15.

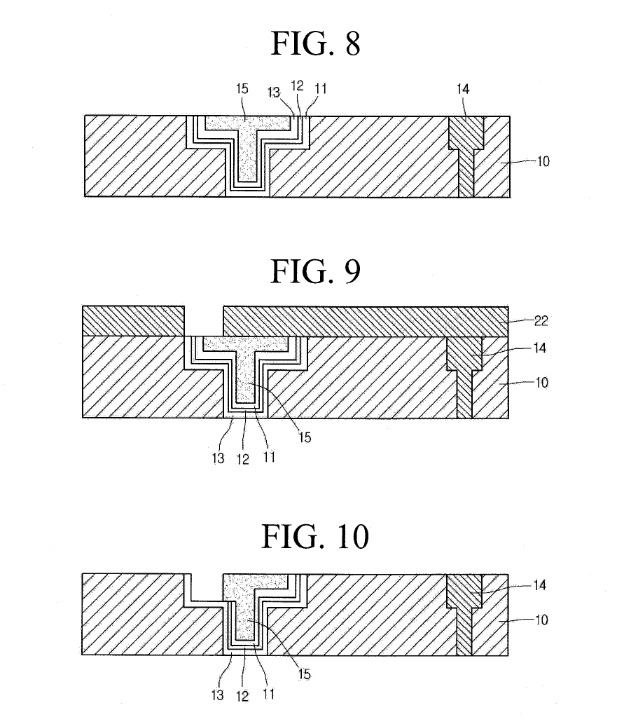

As illustrated in example FIG. 8, third insulating layer 15 is then planarized through a polishing process such as CMP in order that the uppermost surface thereof is coplanar with that of the uppermost surface of first insulating layer 10. Thus, third insulating layer 15 remains only in first structure A so that first structure A has a structure where first metal layer 11, second insulating layer 12, second metal layer 13 and third insulating layer 15 are sequentially laminated therein.

As illustrated in example FIG. 9, second photoresist pattern 22 is then formed by coating a second photoresist on and/or over first insulating layer 10 and then selectively patterning the second photoresist through an exposure and development process. Second patterned photoresist 22 is used as an etch mask. Accordingly, a reticle used for the exposure and development process of second photoresist 22 is aligned on the basis of the stepped portion of first structure A, so that the reticle can be aligned with a lower metal area of the MIM capacitor. Second photoresist pattern 22 is formed such that an opening is formed at a left region of the trench of first structure A thereby exposing a portion of first metal layer 11, second insulating layer 12, second metal layer 13 and third insulating layer 15. Hereinafter, an area of the trench of first structure A at a left side thereof will be referred as a left trench area and an area of the trench of first structure A at a right side thereof will be referred as a right trench area. The left trench area corresponds to the lower metal area of the MIM capacitor.

As illustrated in example FIG. 10, after second photoresist 22 is formed, an etch process such as a wet etch process is performed using second photoresist 22 as an etch mask. The wet etch process is performed to partially remove first metal layer 11, second insulating layer 12 and third insulating layer 15 formed in the left trench area. The region of the left trench area where first metal layer 11, second insulating layer 12 and third insulating layer 15 are partially removed serves as a first opening or space in the trench for forming an electrode of the lower metal area, i.e., a chip bottom metal (CBM) layer. Then, second photoresist 22 is removed.

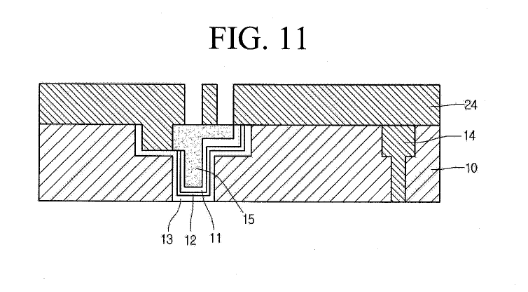

As illustrated in example FIG. 11, third photoresist pattern 24 is formed by coating a third photoresist in the area of the second left trench where first metal layer 11, second insulating layer 12 and third insulating layer 15 are partially removed and coated on and/or over the uppermost surface of first insulating layer 10 including metal interconnection 14 and then selectively patterning the third photoresist through an exposure and development process. Third patterned photoresist 24 is used as an etch mask. Accordingly, a reticle used for the exposure and development process of third photoresist pattern 24 is aligned on the basis of the stepped portion of first structure A, so that the reticle can be aligned with an upper metal area of the MIM capacitor. Third photoresist 24 is patterned such that second and third openings are formed in the trench of first structure A. The openings correspond to the upper metal area of the MIM capacitor. Then, an etch process such as a wet etch process is performed to partially remove a first portion of third insulating layer 15 formed to expose first metal layer 11 formed in the via of first structure A, and partially remove a second portion of third insulating layer 15 to expose the first metal layer formed in the right trench area of first structure A. Third photoresist 24 is removed after completion of the etching.

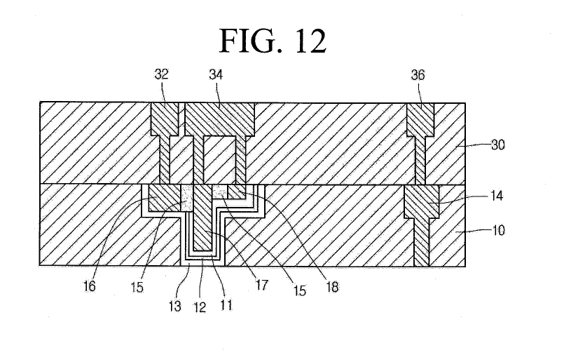

As illustrated in example FIG. 12, a metal layer is then filled in the first opening in the left trench area where first metal layer 11, second insulating layer 12 and third insulating layer 15 are removed to thereby form chip bottom metal (CBM) layer 16 serving as a first electrode of the upper metal area of the MIM capacitor. The metal is simultaneously filled in the second opening in the central region of the trench and via of first structure A where the first portion of third insulating layer 15 is removed, to thereby form first chip top metal (CTM) layer 17 serving as a second electrode of the lower metal area of the MIM capacitor. The metal layer is simultaneously filled in the third opening in the right trench area where the second portion of third insulating layer 15 is removed to thereby form second CTM layer 18 serving as a third electrode of the lower metal area of the MIM capacitor. Third insulating layer 15 remaining among CBM layer 16, first CTM layer 17 and second CTM layer 18 serves as a dielectric layer of the MIM capacitor.

Fourth insulating layer 30 is then formed on and/or over first insulating layer 10 through a subsequent process, a trench and a via are formed through a photolithographic process, and then metal is filled in the trench so that upper metal interconnections 32, 34 and 36 can be formed. First upper metal interconnection 32 can be electrically connected to first CBM layer 16, second upper metal interconnection 34 can be electrically connected to first CTM layer 17 and second CTM layer 18, and third upper metal interconnection 36 can be electrically connected to lower metal interconnection 14.

Since the MIM capacitor and the metal interconnection can be simultaneously formed through the dual trench structure and it is not necessary to laminate a new layer, a stepped portion can be prevented from being generated between device areas. Thus, bad influence exerted upon a subsequent layer structure, such as disconnection between metal interconnections caused by a stepped portion, can be prevented. Next, influence of the stepped portion, which may occur between the layers, is minimized, so that the operation performance of the semiconductor device can be maximized and the defect rate thereof can be minimized. Since the MIM capacitor and the metal interconnection can be simultaneously formed through the dual trench structure, a separate alignment key is not necessary and a manufacturing procedure can be simplified. In addition, the product yield can be maximized. Since the separate alignment key is not necessary and the MIM capacitor and the metal interconnection can be simultaneously formed through the dual trench structure, a substrate area can be efficiently used.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a first insulating layer;
a first structure formed in the first insulating layer;
a second structure formed in the first insulating layer;
a lower metal interconnection formed in the second structure;
a metal-insulator-metal (MIM) capacitor formed in the first structure;
a first electrode formed in the first structure and electrically connected to the MIM capacitor;
a second electrode formed in the first structure and electrically connected to the MIM capacitor; and
a third electrode formed in the first structure and electrically connected to the MIM capacitor.

2. The apparatus of claim 1, wherein the first electrode comprises a chip bottom metal (CBM) layer, the second electrode comprises a first chip top metal (CTM) layer and the third electrode comprises a second chip top metal (CTM) layer.

3. The apparatus of claim 2, wherein the CBM layer is electrically connected to the MIM capacitor at a first portion of the MIM capacitor, the first CTM layer is electrically connected to the MIM capacitor at a second portion of the MIM capacitor, and the second CTM layer is electrically connected to the MIM capacitor at a third portion of the MIM capacitor.

4. The apparatus of claim 1, wherein the first electrode is electrically connected to the MIM capacitor at a first portion of the MIM capacitor, the second electrode is electrically connected to the MIM capacitor at a second portion of the MIM capacitor, and the third electrode is electrically connected to the MIM capacitor at a third portion of the MIM capacitor.

5. The apparatus of claim 5, wherein the first structure and the second structure each comprise a via and a trench.

6. The apparatus of claim 1, further comprising:
a third insulating layer formed in the first structure between the first electrode and the second electrode; and
a fourth insulating layer formed in the first structure between the second electrode and the third electrode.

7. The apparatus of claim 1, further comprising:
a second insulating layer formed over the first insulating layer;
a first upper metal interconnection formed in the second insulating layer and electrically connected to the first electrode;
a second upper metal interconnection formed in the second insulating layer and electrically connected to the second electrode and the third electrode; and
a third upper metal interconnection formed in the second insulating layer and electrically connected to the lower metal interconnection.

8. An apparatus comprising:
a first insulating layer;
a first structure formed in the first insulating layer;
a second structure formed in the first insulating layer spaced from the first structure;
a first metal interconnection formed in the second structure;
a metal-insulator-metal (MIM) capacitor formed in the first structure, the MIM capacitor including a first metal layer, a second insulating layer and a second metal layer;
a first electrode formed in the first structure and electrically connected to the MIM capacitor at the second metal layer;
a second electrode formed in the first structure and electrically connected to the MIM capacitor at the first metal layer;
a third electrode formed in the first structure and electrically connected to the MIM capacitor at the first metal layer;
a third insulating layer formed over the first insulating layer;
a second metal interconnection formed in the third insulating layer and electrically connected to the first electrode;
a third metal interconnection formed in the third insulating layer and electrically connected to the second electrode and the third electrode; and
a fourth metal interconnection formed in the third insulating layer and electrically connected to the first metal interconnection.

9. The apparatus of claim 8, further comprising:
a fourth insulating layer formed in the first structure between the first electrode and the second electrode; and
a fifth insulating layer formed in the first structure between the second electrode and the third electrode.

10. The apparatus of claim 9, wherein the fifth insulating layer is composed of an oxide material.

11. The apparatus of claim 8, wherein the first metal layer and the second metal layer is composed of a metal selected from the group consisting of Ti, TiN, Ti/TiN and Ti/Al/TiN.

12. The apparatus of claim 8, wherein the second insulating layer is composed of a nitride material.

13. The apparatus of claim 8, wherein the first structure and the second structure each comprise a via and a trench.

14. A method comprising:
forming a first structure and a second structure spaced apart in a first insulating layer; and then
forming a lower metal interconnection formed in the second structure; and then
forming a metal-insulator-metal (MIM) capacitor in the first structure; and then
simultaneously forming a second insulating layer pattern and a third insulating layer pattern spaced pattern apart in the first structure; and then
simultaneously forming a first electrode, a second electrode and a third electrode spaced apart in the first structure and electrically connected to the MIM capacitor after simultaneously forming the second insulating layer pattern and the third insulating layer pattern such that the second insulating layer pattern is formed between the first electrode and the second electrode and the third insulating layer pattern is formed between the second electrode and the third electrode.

15. The method of claim 14, wherein the first electrode comprises a chip bottom metal (CBM) layer, the second electrode comprises a first chip top metal (CTM) layer and the third electrode comprises a second chip top metal (CTM) layer.

16. The method of claim 15, wherein the CBM layer is electrically connected to the MIM capacitor at a first portion of the MIM capacitor, the first CTM layer is electrically connected to the MIM capacitor at a second portion of the MIM capacitor, and the second CTM layer is electrically connected to the MIM capacitor at a third portion of the MIM capacitor.

17. The method of claim 14, wherein the first structure and the second structure each comprise a via and a trench.

18. The method of claim 1, further comprising, after simultaneously forming the first electrode, the second electrode and the third electrode:
forming a fourth insulating layer over the first insulating layer; and then
simultaneously forming a first upper metal interconnection in the fourth insulating layer and electrically connected to the first electrode, a second upper metal interconnection in the fourth insulating layer and electrically connected to the second electrode and the third electrode, and a third upper metal interconnection in the fourth insulating layer and electrically connected to the lower metal interconnection.

19. The method of claim 1, wherein the MIM capacitor comprises a first metal layer, a fourth insulating layer and a second metal layer and the first electrode is electrically connected to the MIM capacitor at the second metal layer, and the second and third electrodes are electrically connected to the MIM capacitor at the first metal layer.

20. The method of claim 19, wherein the first metal layer and the second metal layer is composed of a metal selected from the group consisting of Ti, TiN, Ti/TiN and Ti/Al/TiN.
